(19) United States
(12) Patent Application Publication
(10) Pub. No.: US 2025/0221102 A1
(43) Pub. Date: Jul. 3, 2025

(54) MONOLITHIC INTEGRATION OF DIFFERENT LIGHT EMITTING STRUCTURES ON A SAME SUBSTRATE

(71) Applicant: GOOGLE LLC, Mountain View, CA (US)

(72) Inventors: Gang He, Cupertino, CA (US); Sheila K. Hurtt, Palo Alto, CA (US)

(21) Appl. No.: 19/008,173

(22) Filed: Jan. 2, 2025

Related U.S. Application Data
(63) Continuation of application No. 18/305,778, filed on Apr. 24, 2023, now Pat. No. 12,191,418.
Application No. 18/305,778 is a continuation of application No. 16/841,119, filed on Apr. 6, 2020, now Pat. No. 11,637,219.

(51) Int. Cl. H10H 20/821; H10H 20/812; H10H 20/825; H10H 29/14

(52) U.S. Cl. CPC H10H 20/821; H10H 20/812; H10H 20/8252; H10H 29/142

(57) ABSTRACT

The disclosure describes various aspects of monolithic integration of different light emitting structures on a same substrate. In an aspect, a device for light generation is described having a substrate with one or more buffer layers made a material that includes GaN. The device also includes light emitting structures, which are epitaxially grown on a same surface of a top buffer layer of the substrate, where each light emitting structure has an active area parallel to the surface and laterally terminated, and where the active area of different light emitting structures is configured to directly generate a different color of light. The device also includes a p-doped layer disposed over the active area of each light emitting structure and made of a p-doped material that includes GaN. The device may be part of a light field display and may be connected to a backplane of the light field display.

### CROSS REFERENCE TO RELATED APPLICATIONS

This application is a continuation of U.S. application Ser. No. 18/305,778, filed Apr. 24, 2023, which is a continuation of U.S. application Ser. No. 16/841,119, filed Apr. 6, 2020, which claims priority to and the benefit of U.S. Provisional Application No. 62/833,072, filed on Apr. 12, 2019, the disclosures of which are incorporated herein by reference in their entireties.

### BACKGROUND OF THE DISCLOSURE

Aspects of the present disclosure generally relate to light emitting structures, such as the structures of light emitting elements used in various types of displays, and more specifically, to monolithically integrating light emitting structures that generate different colors of light on a same substrate.

As the number of light emitting elements (e.g., pixels) used in displays continues to increase to provide better user experience and to enable new applications, adding more and more of them becomes a challenge from both a design and manufacturing perspective. To achieve ever smaller light emitting elements in order to increase both count and density has made the potential use of small light-emitting diodes (LEDs) more attractive; however, effective and efficient techniques for making small LEDs in large numbers, high densities, and capable of producing the different colors (e.g., red, green, blue) needed for a color display are not widely available, and those that do exist tend to be cumbersome, time consuming, and costly. In addition, making use of these small LEDs in more sophisticated display architectures with more stringent requirements in terms of both performance and size, such as light field displays, becomes a rather difficult thing to do.

Accordingly, techniques and devices that enable effective and efficient design and fabrication of large numbers of small light emitting elements by monolithically integrating semiconductor structures that generate different colors of light on a same substrate (e.g., a single integrated semiconductor device) are desirable.

### SUMMARY OF THE DISCLOSURE

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its purpose is to present some concepts of one or more aspects in a simplified form as a prelude to the more detailed description that is presented later.

In an aspect of the disclosure, a device for light generation is described having a substrate with one or more buffer layers made a material that includes GaN. The device also includes light emitting structures, which are epitaxially grown on a same surface of a top buffer layer of the substrate, where each light emitting structure has an active area parallel to the surface and laterally terminated, and where the active area of different light emitting structures is configured to directly generate a different color of light. The device also includes a p-doped layer disposed over the active area of each light emitting structure and made of a p-doped material that includes GaN. The device may be part of a light field display and may be connected to a backplane of the light field display.

### BRIEF DESCRIPTION OF THE DRAWINGS

The appended drawings illustrate only some implementation and are therefore not to be considered limiting of scope.

FIG. 1 illustrates an example of a display and a source of content for the display, in accordance with aspects of this disclosure.

FIG. 2A illustrates an example of a display having multiple pixels, in accordance with aspects of this disclosure.

FIGS. 2B and 2C illustrate examples of a light field display having multiple picture elements, in accordance with aspects of this disclosure.

FIG. 2D illustrates an example of a cross-sectional view of a portion of a light field display, in accordance with aspects of this disclosure.

FIG. 3 illustrates an example of a backplane integrated with an array of light emitting elements, in accordance with aspects of this disclosure.

FIG. 4A illustrates an example of an array of light emitting elements in a picture element, in accordance with aspects of this disclosure.

FIG. 4B illustrates an example of a picture element with sub-picture elements, in accordance with aspects of this disclosure.

FIG. 5A illustrates a cross sectional view of an example of multiple light emitting structures monolithically integrated on a substrate, in accordance with aspects of this disclosure.

FIG. 5B illustrates a cross sectional view of another example of multiple light emitting structures monolithically integrated on a substrate, in accordance with aspects of this disclosure.

FIG. 6A illustrates a cross sectional view of an example of a device with multiple light emitting structures, in accordance with aspects of this disclosure.

FIG. 6B illustrates a cross sectional view of the device of FIG. 6A connected to a backplane, in accordance with aspects of this disclosure.

FIG. 6C illustrates a cross sectional view of another example of a device with multiple light emitting structures, in accordance with aspects of this disclosure.

FIG. 6D illustrates a cross sectional view of the device of FIG. 6C connected to a backplane, in accordance with aspects of this disclosure.

FIGS. 7A-7C illustrate cross sectional views of examples of light emitting structure, in accordance with aspects of this disclosure.

FIGS. 8A and 8B illustrate cross sectional views of arrays or groups of one type of light emitting structure, in accordance with aspects of this disclosure.

FIGS. 8C and 8D illustrate cross sectional views of arrays or groups of another type of light emitting structure, in accordance with aspects of this disclosure.

FIGS. 9A and 9B illustrate diagrams of different examples of arrangements of devices for light generation in a display, in accordance with aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components are shown in block diagram form in order to avoid obscuring such concepts.

As mentioned above, with a need for ever increasing numbers of light emitting elements (e.g., pixels) in displays to provide better user experience and to enable new applications, adding more and more of them becomes a challenge. To achieve ever smaller light emitting elements in order to increase both count and density has made the potential use of small LEDs (e.g., micro-LEDs) more attractive, but the few techniques for making small LEDs in large numbers, high densities, and capable of producing the different colors (e.g., red, green, blue) are currently cumbersome, time consuming, and costly. More sophisticated display architectures, such as those for light field displays, may benefit from the use of small LEDs, but the requirements of such displays makes the implementation of small LEDs a rather difficult thing to do. Accordingly, new techniques and devices that allow for the monolithic integrating of large numbers of small light emitting structures that generate different colors of light on a same substrate (e.g., a single integrated semiconductor device) are desirable.

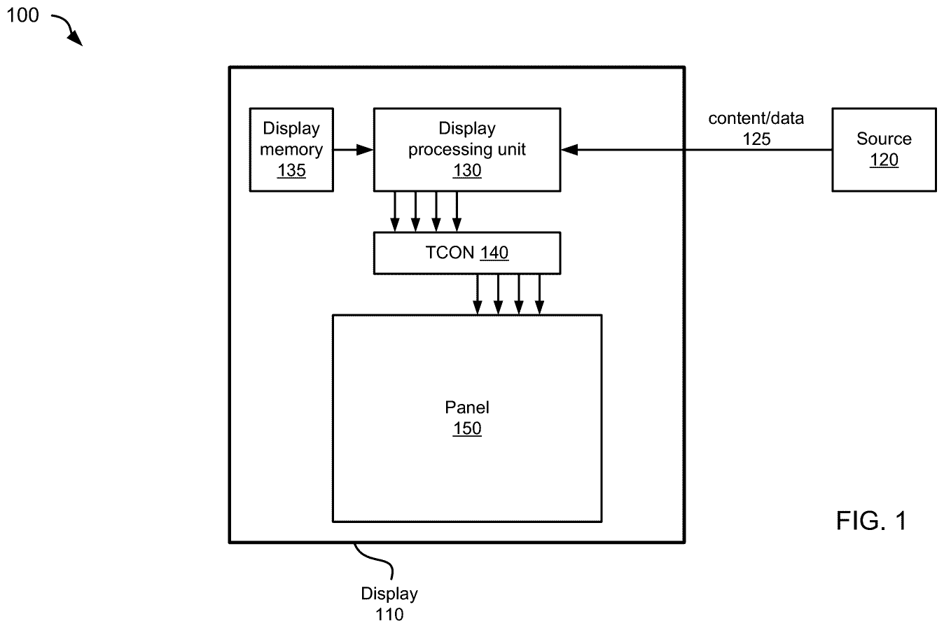

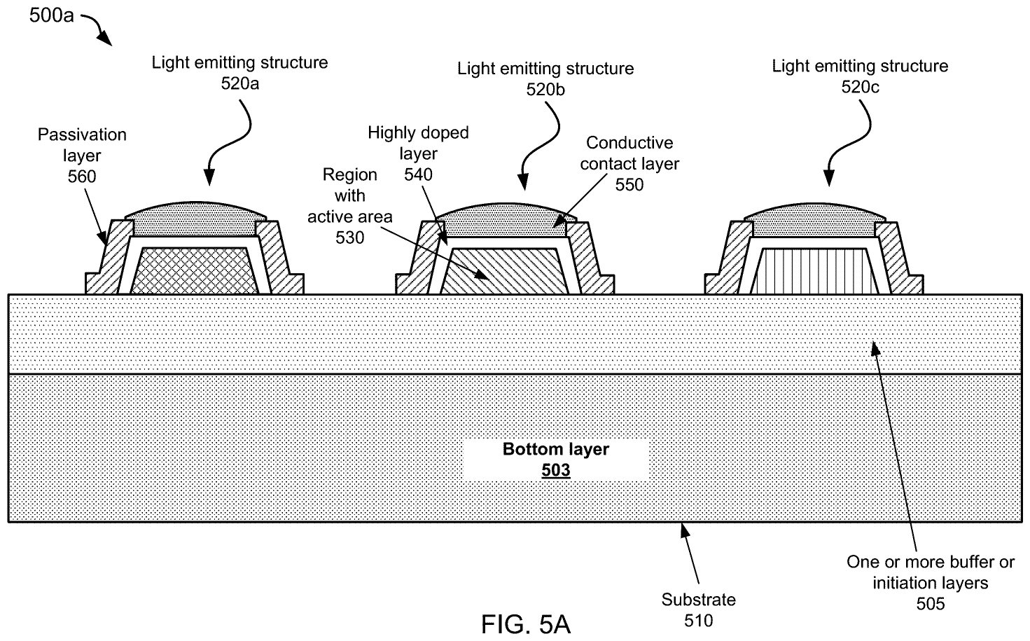

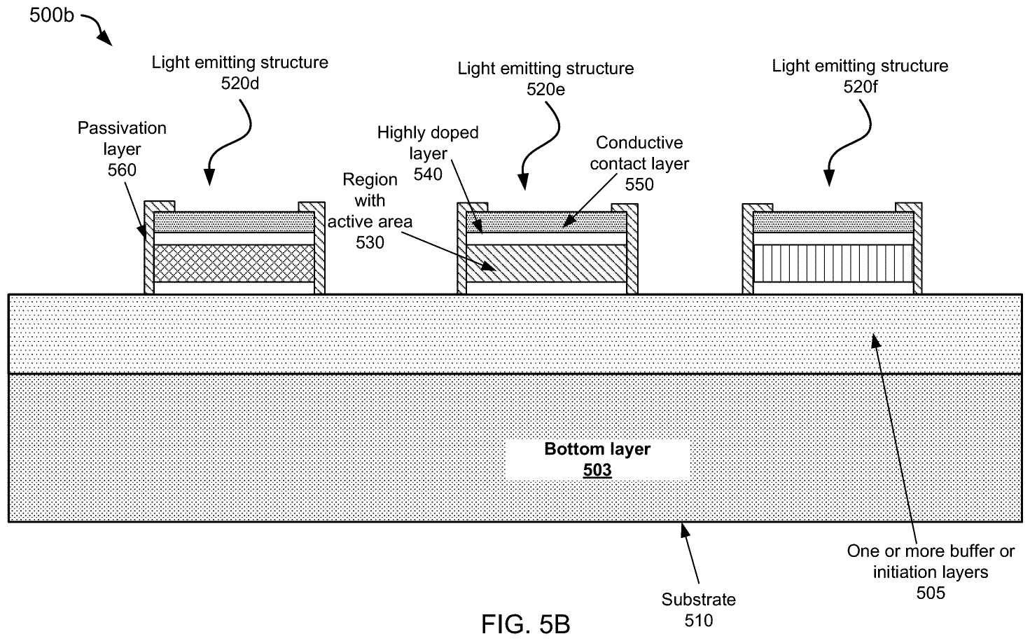

This disclosure, in connection with the figures described below, provides examples of such techniques and devices. For example, FIGS. 1-4B describe general information about examples of displays in which monolithically integrated light emitting structures may be implemented, while FIGS. 5A-9B describe various aspects of examples of such monolithically integrated light emitting structures.

As used in this disclosure, the term “light emitting structure” and “light emitting element” may be used interchangeably, where the term “light emitting structure” may be used to describe a structural arrangement (e.g., materials, layers, configuration) of a single component configured to produce light of a particular color, and the terms a “light emitting element,” “light emitter,” or simply “emitter” may be used to more generally refer to the single component.

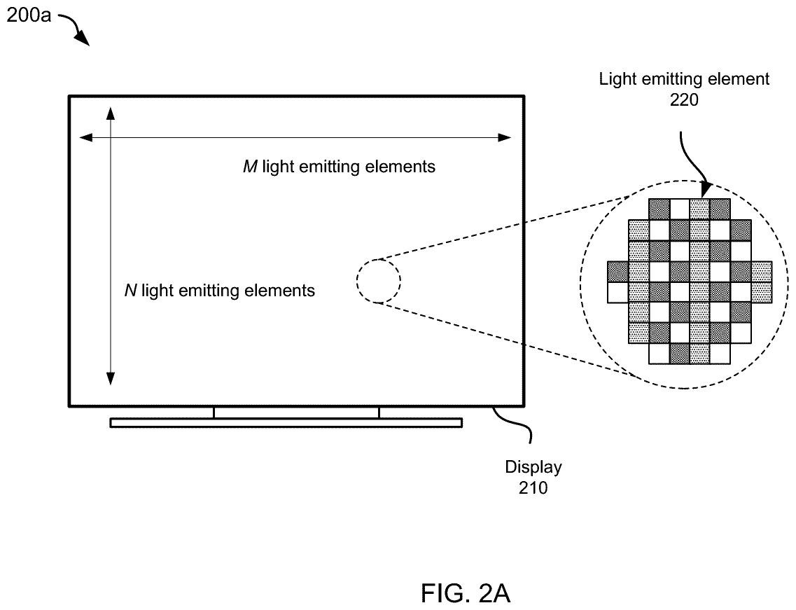

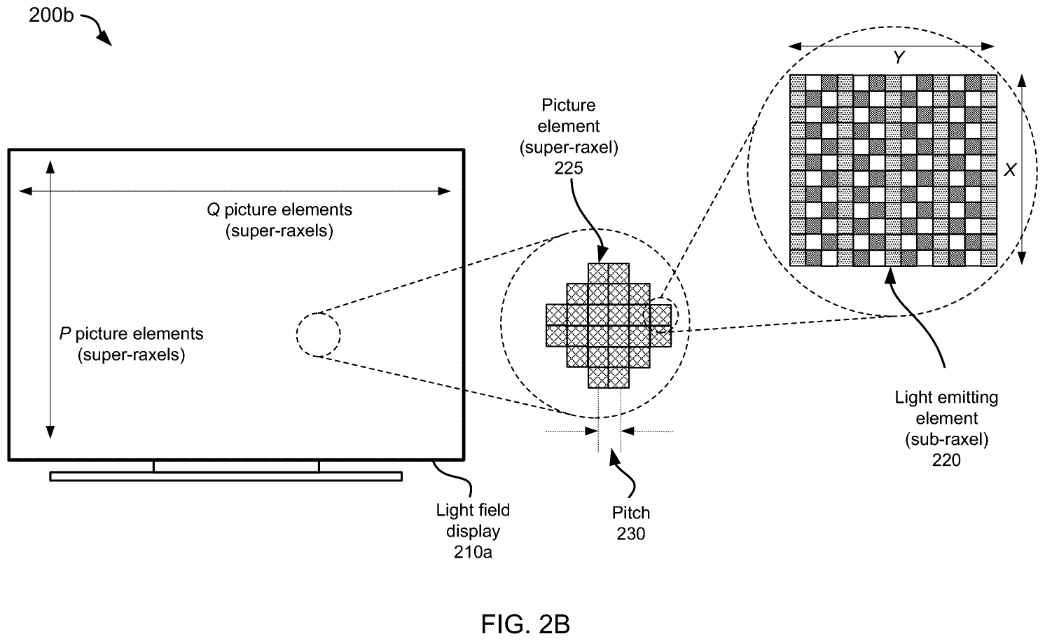

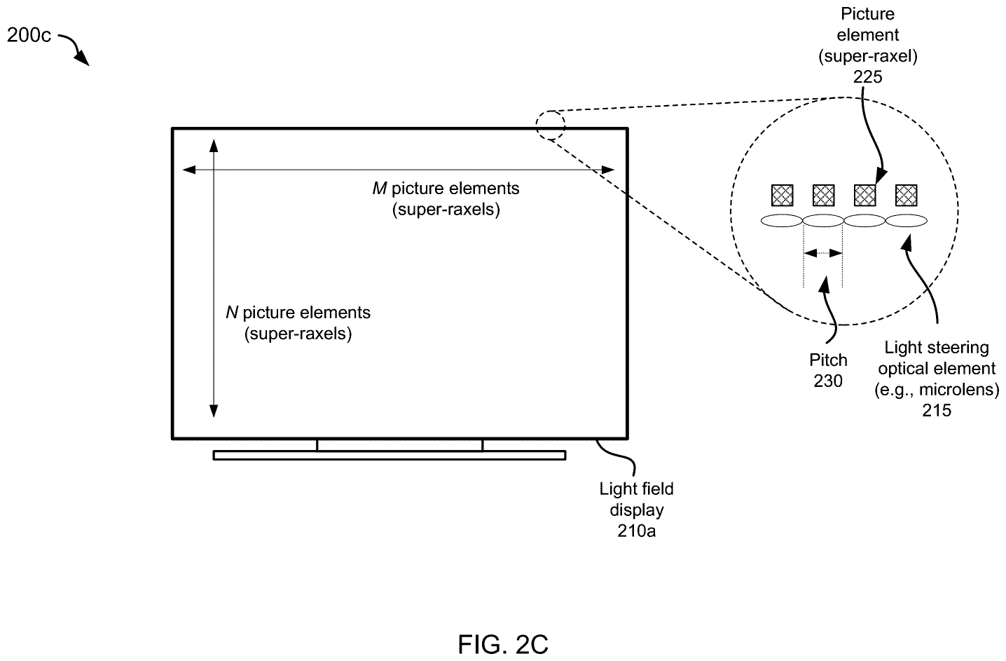

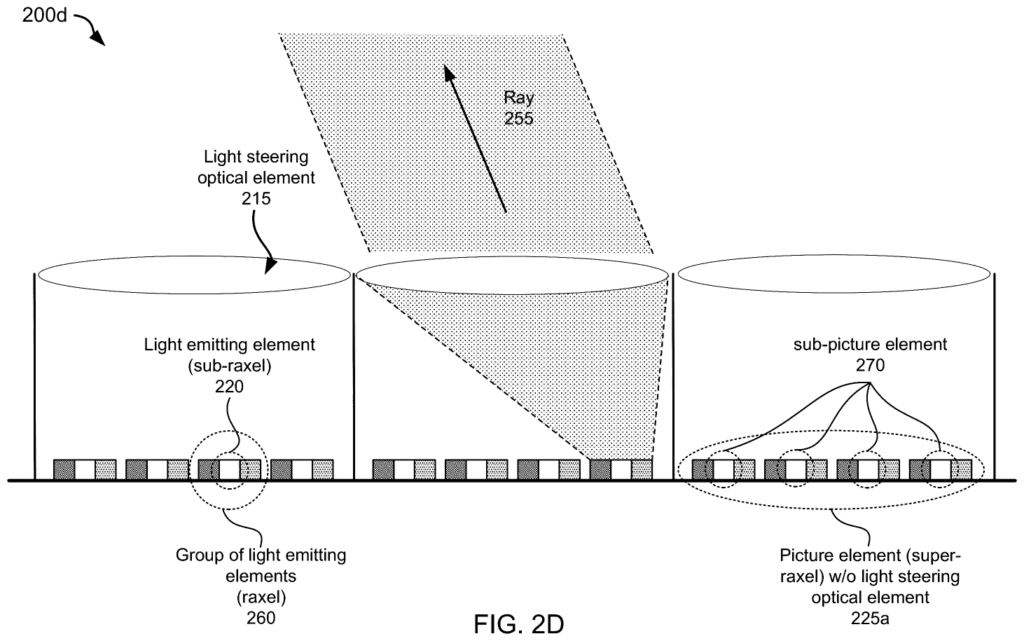

FIG. 1 shows a diagram 100 that illustrates an example of a display 110 that receives content/data 125 (e.g., image content, video content, or both) from a source 120. The display 110 may include one or more panels 150 (one is shown), where each panel 150 in the display 110 is a light emitting panel or a reflective panel. The panel may include not only light emitting or light reflecting elements in some arrangement or array, but may also include a backplane for driving the light emitting or light reflecting elements. When light emitting panels are used they can include multiple light emitting elements (see e.g., light emitting elements 220 in FIG. 2A).

These light emitting elements can be LEDs made from one or more semiconductor materials. The LEDs can be an inorganic LEDs. The LEDs can be, for example, micro-LEDs, also referred to as microLEDs, mLEDs, or μLEDs. Other display technologies from which the light emitting elements can be made include liquid crystal display (LCD) technology or organic LED (OLED) technology. Moreover, LEDs that produce different colors of light may be monolithically integrated into a same semiconductor substrate for efficient fabrication.

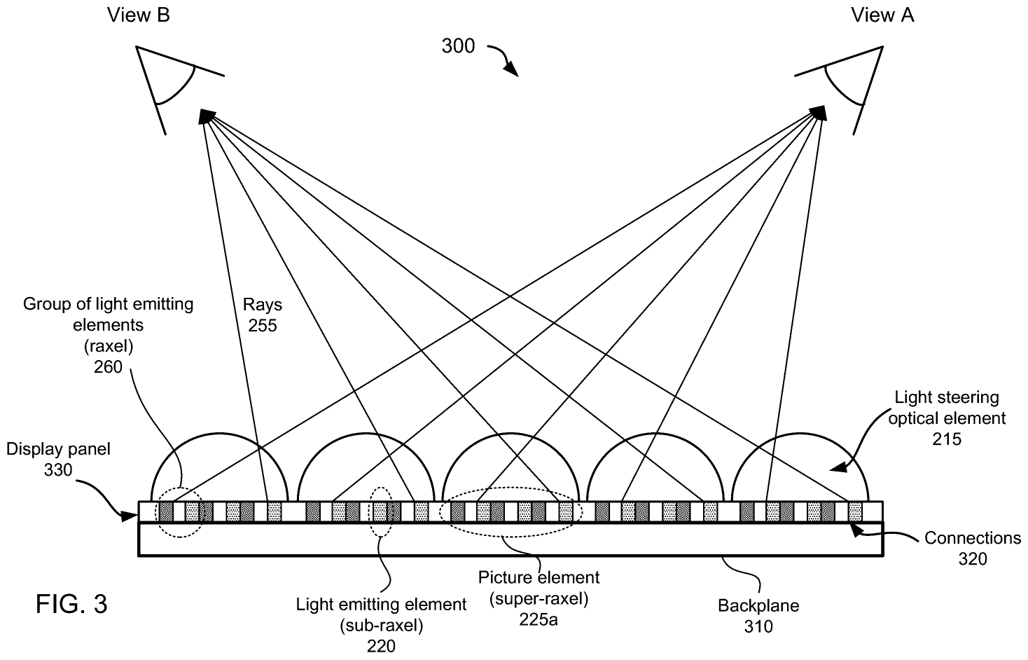

The display 110 can have capabilities that include ultra-high-resolution capabilities (e.g., support for resolutions of 8K and higher), high dynamic range (contrast) capabilities, or light field capabilities, or a combination of these capabilities. When the display 110 has light field capabilities and can operate as a light field display, the display 110 can include multiple picture elements (e.g., super-raxels), where each picture element has a respective light steering optical element and an array of light emitting elements (e.g., sub-raxels) monolithically integrated on a same semiconductor substrate, and where the light emitting elements in the array are arranged into separate groups (e.g., raxels) to provide multiple views supported by the light field display (see e.g., FIGS. 2B-3). Moreover, for light field displays, the numbers of light emitting elements and their density may be orders of magnitude greater than for conventional displays, even high-resolution ones.

The source 120 may provide the content/data 125 to a display processing unit 130 integrated within the display 110. The display processing unit 130 may be configured to modify an image or video content in the content/data 125 for presentation by the display 110. A display memory 135 is also shown that stores information used by the display processing unit 130 for handing the image or video content. The display memory 135, or a portion of it, can be integrated with the display processing unit 130. The set of tasks that can be performed by the display processing unit 130 may include tasks associated with color management, data conversion, and/or multiview processing operations for light field applications. The display processing unit 130 may provide processed content/data to a timer controller (TCON) 140, which in turn provides the appropriate display information to the panel 150. At mentioned above, the panel 150 (also referred to as a display panel) can include a backplane for driving light emitting or light reflecting elements in the panel 150.

A diagram 200a in FIG. 2A shows a display 210 having multiple light emitting elements 220, typically referred to as pixels or display pixels. As mentioned above, these light emitting elements may be made of certain structures (e.g., semiconductor structures) that allow for light emitting elements that produce different colors to be monolithically integrated on a same substrate. The light emitting elements 220, although shown separated from each other for illustration purposes, are generally formed in an array and adjacent to each other to provide for a higher resolution of the display 210. The display 210a may be an example of the display 110 in the diagram 100.

In the example shown in FIG. 2A, the light emitting elements 220 can be organized or positioned into an N×M array, with N being the number of rows of pixels in the array and M being the number of columns of pixels in the array. An enlarged portion of such an array is shown to the right of the display 210. For small displays, examples of array sizes can include N≥10 and M≥10 and N≥100 and M≥100. For larger displays, examples of array sizes can include N≥500 and M≥500, N≥1,000 and M≥1,000, N≥5,000 and M≥5,000, N≥10,000 and M≥10,000, with even larger array sizes also possible.

Although not shown, the display 210 may include, in addition to the array of light emitting elements 220, a backplane for driving the array. The backplane may be configured to enable low power consumption and high bandwidth operation.

A diagram 200b in FIG. 2B shows a light field display 210a having multiple picture elements or super-raxels 225. In this disclosure, the term “picture element” and the term “super-raxel” can be used interchangeably to describe a similar structural unit in a light field display. The light field display 210a may be an example of the display 110 in the diagram 100 having light field capabilities. The light field display 210a can be used for different types of applications and its size may vary accordingly. For example, a light field display 210a can have different sizes when used as displays for watches, near-eye applications, phones, tablets, laptops, monitors, televisions, and billboards, to name a few. Accordingly, and depending on the application, the picture elements 225 in the light field display 210a can be organized into arrays, grids, or other types of ordered arrangements of different sizes. The picture elements 225 of the light field display 210a can be distributed over one or more display panels.

In the example shown in FIG. 2B, the picture elements 225 can be organized or positioned into an P×Q array, with P being the number of rows of picture elements in the array and Q being the number of columns of picture elements in the array. An enlarged portion of such an array is shown to the right of the light field display 210a. For small displays, examples of array sizes can include P≥10 and Q≥10 and P≥100 and Q≥100. For larger displays, examples of array sizes can include P≥500 and Q≥500, P≥1,000 and Q≥1,000, P≥5,000 and Q≥5,000, and P≥10,000 and Q≥10,000.

Each picture element 225 in the array has itself an array or grid of light emitting elements 220 or sub-raxels (as shown further to the right). In other words, each picture element 225 includes multiple light emitting elements 220, and each of those light emitting elements 225 includes a respective light emitting structure. When the picture elements 225 include as light emitting elements 220 different LEDs on a same semiconductor substrate that produce different colors of light, e.g., red (R) light, green (G) light, and blue (B) light, the light field display 210a can be said to be made from monolithically integrated RGB LED super-raxels.

Each of the picture elements 225 in the light field display 210a, including its corresponding light steering optical element 215 (an integral imaging lens illustrated in a diagram 200c in FIG. 2C), can represent a minimum picture element size limited by display resolution. In this regard, an array or grid of light emitting elements 220 of a picture element 225 can be smaller than the corresponding light steering optical element 215 for that picture element. In practice, however, it is possible for the size of the array or grid of light emitting elements 220 of a picture element 225 to be similar to the size of the corresponding light steering optical element 215 (e.g., the diameter of a microlens or lenslet), which in turn can be similar or the same as a pitch 230 between picture elements 225.

As mentioned above, an enlarged version of an array of light emitting elements 220 for a picture element 225 is shown to the right of the diagram 200b. The array of light emitting elements 220 can be an X×Y array, with X being the number of rows of light emitting elements 220 in the array and Y being the number of columns of light emitting elements 220 in the array. Examples of array sizes can include X≥5 and Y≥5, X≥8 and Y≥8, X≥9 and Y≥9, X≥10 and Y≥10, X≥12 and Y≥12, X≥20 and Y≥20, and X≥25 and Y≥25. In an example, a X×Y array may be a 9×9 array including 81 light emitting elements or sub-raxels 220.

For each picture element 225, the light emitting elements 220 in the array can include separate and distinct groups of light emitting elements 220 (see e.g., group of light emitting elements 260 in FIG. 2D) that are allocated or grouped (e.g., logically grouped) based on spatial and angular proximity and that are configured to produce the different light outputs (e.g., directional light outputs) that contribute to produce light field views provided by the light field display 210a to a viewer. The grouping of sub-raxels or light emitting elements 220 into raxels need not be unique. For example, during assembly or manufacturing, there can be a mapping of sub-raxels into particular raxels that best optimize the display experience. A similar re-mapping can be performed by the display once deployed to account for, for example, aging of various parts or elements of the display, including variations in the aging of light emitting elements of different colors and/or in the aging of light steering optical elements. In this disclosure, the term “groups of light emitting elements” and the term “raxel” can be used interchangeably to describe a similar structural unit in a light field display. The light field views produced by the contribution of the various groups of light emitting elements or raxels can be perceived by a viewer as continuous or non-continuous views. As mentioned above, the structures of the various light emitting elements that generate light of different colors may all be monolithically integrated on a same semiconductor substrate, which is described in more detail below.

Each of the groups of light emitting elements 220 in the array of light emitting elements 220 (far right of the diagram 200b in FIG. 2B) includes light emitting elements that produce at least three different colors of light (e.g., red light, green light, blue light, and perhaps also white light). In one example, each of these groups or raxels includes at least one light emitting element 220 that produces red light, one light emitting element 220 that produces green light, and one light emitting element 220 that produce blue light. Alternatively, at least one light emitting element 220 that produces white light may also be included.

In FIG. 2C, a diagram 200c shows another example of the light field display 210a illustrating an enlarged view of a portion of an array of picture elements 225 with corresponding light steering optical elements 215 as described above. The pitch 230 can represent a spacing or distance between picture elements 225 and can be about a size of the light steering optical element 215 (e.g., size of a microlens or lenslet).

A diagram 200d in FIG. 2D shows a cross-sectional view of a portion of a light field display (e.g., the light field display 210a) to illustrate some of the structural units described in this disclosure for when the display 110 in FIG. 1 is configured as a light field display. For example, the diagram 200d shows three adjacent picture elements or super-raxels 225a, each having a corresponding light steering optical element 215. In this example, the light steering optical element 215 can be considered separate from the picture element 220a but in other instances the light steering optical element 215 can be considered to be part of the picture element.

As shown in FIG. 2D, each picture element 225a includes multiple light emitting elements 220 (e.g., multiple sub-raxels), where several light emitting elements 220 (e.g., several sub-raxels) of different types can be grouped together into the group 260 (e.g., into a raxel). A group or raxel can produce various components that contribute to a particular ray element 255 as shown by the right-most group or raxel in the middle picture element 225a. Is it to be understood that the ray elements 255 produced by different groups or raxels in different picture elements can contribute to a view perceived by viewer away from the light field display.

An additional structural unit described in FIG. 2D is the concept of a sub-picture element 270, which represents a grouping of the light emitting elements 220 of the same type (e.g., produce the same color of light) of the picture element 225a.

FIG. 2D also supports the concept of having various light emitting elements 220 (or at least their respective structures configured to produce light) configured to produce different colors of light, whether in a picture element 225 (super-raxel), a group 260 (raxel), or a sub-picture element 270, monolithically integrated on a same or single semiconductor substrate.

A diagram 300 in FIG. 3 illustrates an example of a backplane integrated with an array of light emitting elements. The diagram 300 shows a cross-sectional view, similar to that in the diagram 200d in FIG. 2D. The diagram 300 shows the light emitting optical elements (sub-raxels) 220, the groups of light emitting elements (raxels) 260, the picture elements (super-raxels) 225a, and the light steering optical elements 215. Also shown is a representation of how various rays 255 from different picture elements may contribute to produce different views, such as view A and view B. Moreover, the light emitting elements 220 of the picture elements 225a form a larger array 330 (e.g., a display panel) that is then connected to a backplane 310 through connections 320, which in turn is configured to drive each of the light emitting elements 220.

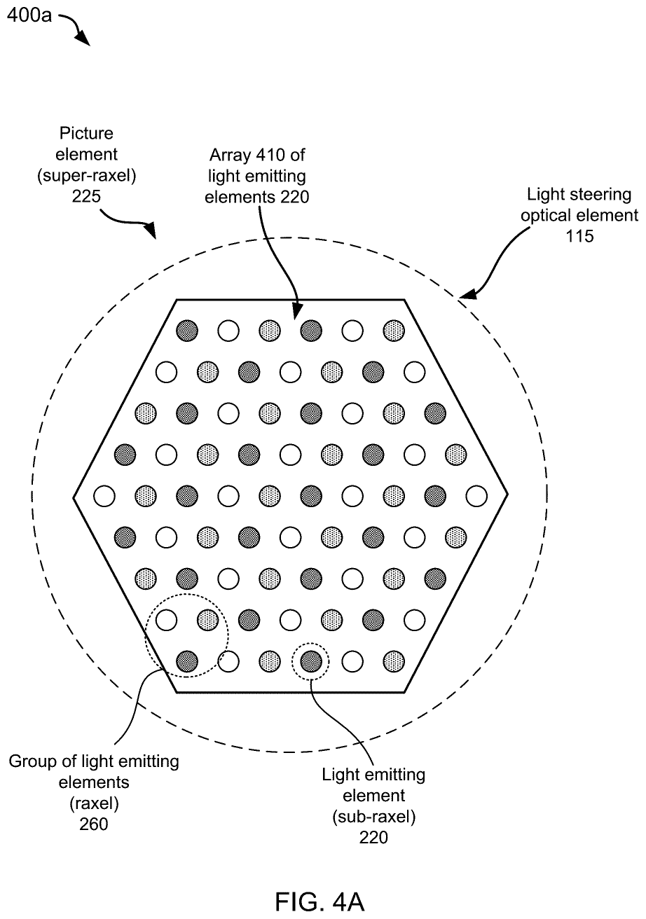

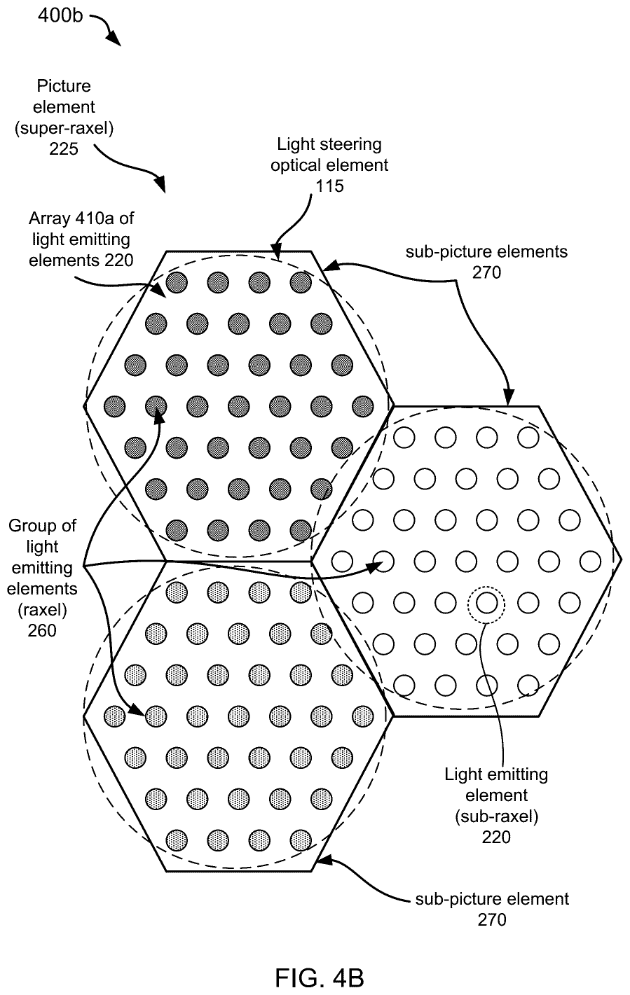

FIG. 4A shows a diagram 400a describing various details of one implementation of a picture element 225. For example, the picture element 225 (e.g., a super-raxel) has a respective light steering optical element 215 (shown with a dashed line) and includes an array or grid 410 of light emitting elements 220 (e.g., sub-raxels) monolithically integrated on a same semiconductor substrate. The light steering optical element 215 can be of the same or similar size as the array 410, or could be slightly larger than the array 410 as illustrated. It is to be understood that some of the sizes illustrated in the figures of this disclosure have been exaggerated for purposes of illustration and need not be considered to be an exact representation of actual or relative sizes.

The light emitting elements 220 in the array 410 include different types of light emitting elements to produce light of different colors and are arranged into separate groups 260 (e.g., separate raxels) that provide different contributions to the multiple views produced by a light field display. Each of the light emitting elements 220 in the array 410 can be monolithically integrated on a same semiconductor substrate.

As shown in FIG. 4A, the array 410 has a geometric arrangement to allow adjacent or close placement of two or more picture elements. The geometric arrangement can be one of a hexagonal shape (as shown in FIG. 4A), a square shape, or a rectangular shape.

Although not shown, the picture element 225 in FIG. 4A can have corresponding electronic means (e.g., in a backplane) that includes multiple driver circuits configured to drive the light emitting elements 220 in the picture element 225.

FIG. 4B shows a diagram 400b describing various details of another implementation of a picture element 225. For example, the picture element 225 (e.g., a super-raxel) in FIG. 4B includes multiple sub-picture elements 270 monolithically integrated on a same semiconductor substrate. Each sub-picture element 270 has a respective light steering optical element 215 (shown with a dashed line) and includes an array or grid 410a of light emitting elements 220 (e.g., sub-raxels) that produce the same color of light. The light steering optical element 215 can be of the same or similar size as the array 410a, or could be slightly larger than the array 410a as illustrated. For the picture element 225, the light steering optical element 215 of one of the sub-picture elements 270 is configured to optimize the chromatic dispersion for a color of light produced by the light emitting elements 220 in that sub-picture element 720. Moreover, the light steering optical element 215 can be aligned and bonded to the array 410a of the respective sub-picture element 270.

The light emitting elements 220 of the sub-picture elements 720 are arranged into separate groups 260 (e.g., raxels). As illustrated by FIG. 4B, in one example, each group 260 can include collocated light emitting elements 220 from each of the sub-picture elements 270 (e.g., same position in each sub-picture element). As mentioned above, however, the mapping of various light emitting elements 220 to different groups 260 can be varied during manufacturing and/or operation. Each of the light emitting elements 220 in the various sub-picture elements 270 can be monolithically integrated on a same semiconductor substrate.

As shown in FIG. 4B, the array 410a has a geometric arrangement to allow adjacent placement of two or more sub-picture elements. The geometric arrangement can be one of a hexagonal shape (as shown in FIG. 4B), a square shape, or a rectangular shape.

Although not shown, the picture element 225 in FIG. 4B can have corresponding electronic means (e.g., in a backplane) that includes multiple driver circuits configured to drive the light emitting elements 220 in the picture element 225. In some examples, one or more common driver circuits can be used for each of the sub-picture elements 270.

As mentioned above, FIGS. 1-4B describe general information about examples of displays in which monolithically integrated light emitting structures (e.g., the structures of the light emitting elements 220) may be implemented. The description of FIGS. 5A-9B below provide details regarding various aspects of examples of such monolithically integrated light emitting structures.

A diagram 500a in FIG. 5A illustrates a cross sectional view of an example in which light emitting structures 520a, 520b, and 520c are monolithically integrated on a substrate 510 (e.g., a semiconductor substrate). The substrate 510 may part of a device and may be made of multiple layers. In one example, the substrate 510 may include a bottom layer 503 (e.g. a layer made of sapphire) and one or more buffer or initiation layers 505 disposed over the bottom layer. The buffer layers 505 may include, for example, a first buffer layer 505 made of undpoded GaN and a second buffer layer 505 made of n-doped GaN, the latter of the two forming a top layer of the substrate 510. In some examples, the second buffer layer 505 may be thicker than the first buffer layer 505. Although the bottom layer of the substrate 510 need not be a semiconductor layer, the substrate 510 may be referred to as a semiconductor substrate since one or more of the top layers (e.g., the buffer or initiation layers 505) are semiconductor layers.

On a top surface of the substrate 510 (e.g., on a surface of the top buffer layer 505), in an optional example, a dielectric (not shown) may be deposited that defines the placement or positioning of the various light emitting structures 520a, 520b, and 520c to be grown. In such an example, the dielectric may be used to configure or arrange the light emitting structures 520 in the types of implementations described above in connection with FIGS. 2A, 2B, 2D, 3, 4A, and 4B.

The light emitting structure 520a may be configured to be part of or correspond to a light emitting element (e.g., light emitting element 220) that produces a first color of light, while the light emitting structures 520b and 520c may be configured to be part of or correspond to light emitting elements that produce a second color of light and a third color of light, respectively. Although not shown, other light emitting structures may also be included to produce additional colors of light.

Additional details of the layers, assembly, or configuration of a light emitting structure are provided in the diagram 500a of FIG. 5A in connection with the light emitting structure 520b shown in the middle. For example, a light emitting structure, which again may be part of or may correspond to a light emitting element, may include an epitaxially grown region 530 having an active area (e.g., an area that is used to generate the light), a highly doped layer 540 (e.g., made of a p++ doped material) deposited over the region 530, and a conductive contact layer 550 (e.g., metal or transparent conductor, also referred to as p-contact or p-contact layer) deposited over the highly doped layer 540. There may also be a passivation layer 560 deposited over the sides of the highly doped layer 540 (and possibly partially over the top of the highly doped layer 540). The active area in the region 530 may include at least one quantum well, whether in the form of individual quantum well structures or multiquantum well (MQW) structures within the region 530. Additionally or alternatively, the active area in the region 530 may include one or more rare earths, the choice of rare earth depending on the color of light to be generated. It is to be understood that the light emitting structures 520a and 520b are similarly constructed, however, each may have a different region 530 (and thus a different active area) to produce different colors of light. The light emitting structures 520a, 520b, and 520c are therefore considered to be monolithically integrated on the single substrate 510.

In this example, the conductive contact layer 550 only covers a top portion of the highly doped layer 540. This may be achieved by depositing the passivation layer 560 before the conductive contact layer 550, for example.

The sides of the light emitting structures 520a, 520b, and 520c may be faceted, that is, may not be vertical but have instead an angle or slant. This is reflected in the configuration of the sides or sidewalls of the region 530, the highly doped layer 540, and the passivation layer 560.

A diagram 500b in FIG. 5B illustrates a cross sectional view of another example in which light emitting structures 520e, 520d, and 520f are monolithically integrated on the substrate 510 (e.g., a semiconductor substrate). The substrate 510 may be part of a device and may be the same or similar to the one shown in the diagram 500a in FIG. 5A, and may include the bottom layer 503 and the one or more buffer or initiation layers 505. The various light emitting structures 520d, 520e, and 520f may be grown in particular positions or places by using different semiconductor fabrication techniques, allowing the light emitting structures to be configured or arranged in the types of implementations described above in connection with FIGS. 2A, 2B, 2D, 3, 4A, and 4B.

The light emitting structure 520d may be configured to be part of or correspond to a light emitting element (e.g., light emitting element 220) that produces a first color of light, while the light emitting structures 520e and 520f may be configured to be part of or correspond to light emitting elements that produce a second color of light and a third color of light, respectively. Although not shown, other light emitting structures may also be included to produce additional colors of light.

Additional details of the layers, assembly, or configuration of a light emitting structure are provided in the diagram 500b of FIG. 5B in connection with the light emitting structure 520e shown in the middle. For example, a light emitting structure, which again may be part of or may correspond to a light emitting element, may include the epitaxially grown region 530 having an active area, the highly doped layer 540, and the conductive contact layer 550. There may also be a passivation layer 560 deposited over the sides of the light emitting structure (and possibly partially over the top). The active area in the region 530 may include at least one quantum well, whether in the form of individual quantum well structures or multiquantum well (MQW) structures within the region 530. Additionally or alternatively, the active area in the region 530 may include one or more rare earths, the choice of rare earth depending on the color of light to be generated. It is to be understood that the light emitting structures 520d and 520f are similarly constructed, however, each may have a different region 530 (and thus a different active area) to produce different colors of light. The light emitting structures 520d, 520e, and 520f are therefore considered to be monolithically integrated on the single substrate 510. The sides or sidewalls of the light emitting structures 520d, 520e, and 520f may be vertical, which may be accomplished by different semiconductor fabrication techniques and in accordance with the processes used to make the structures.

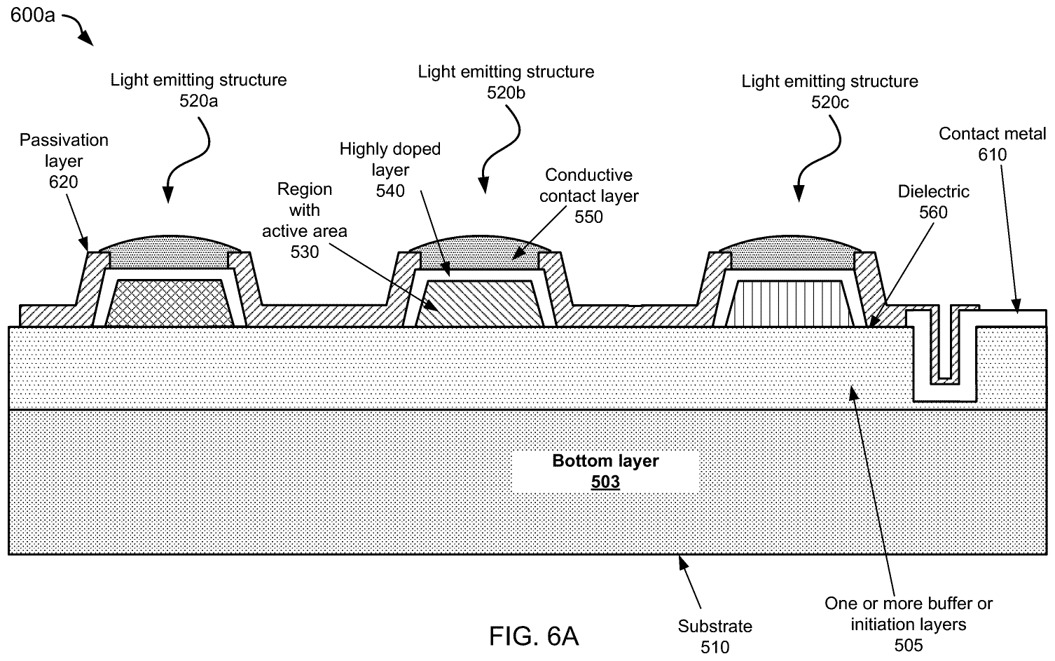

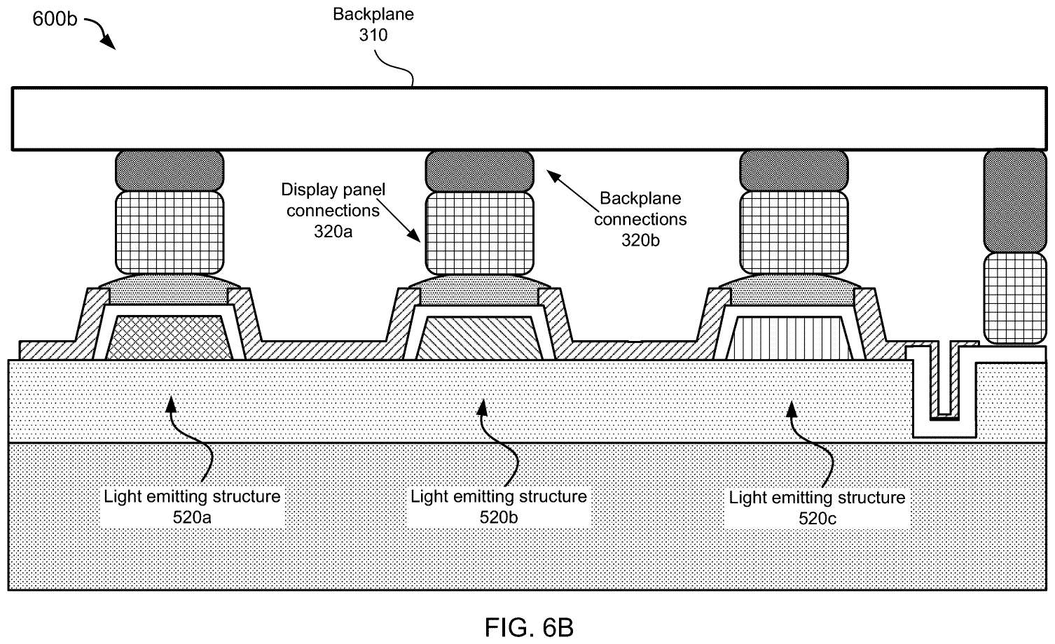

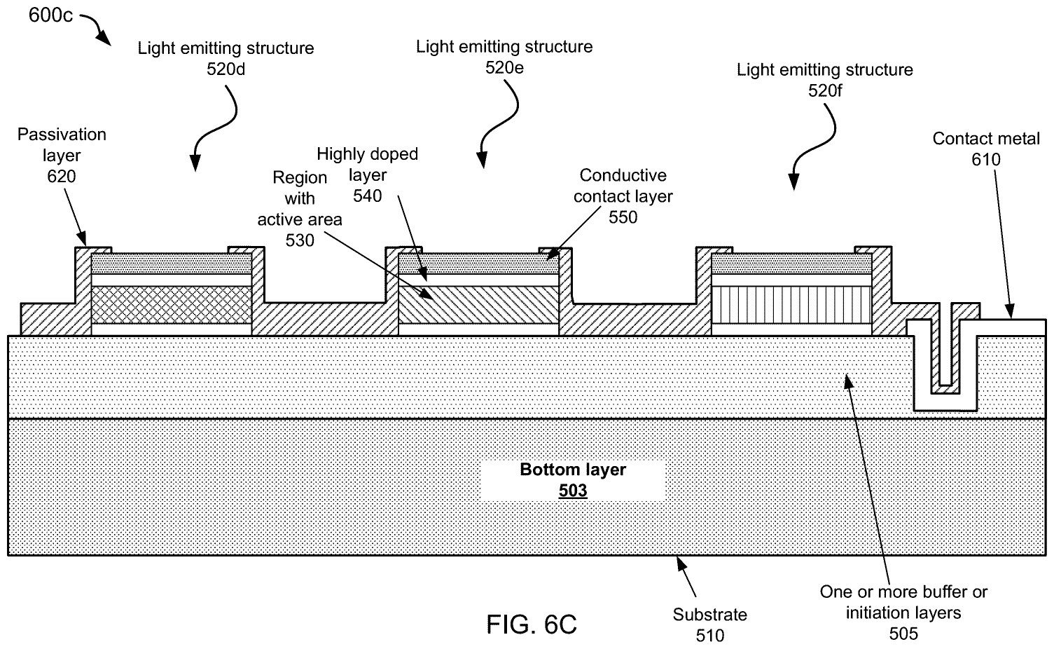

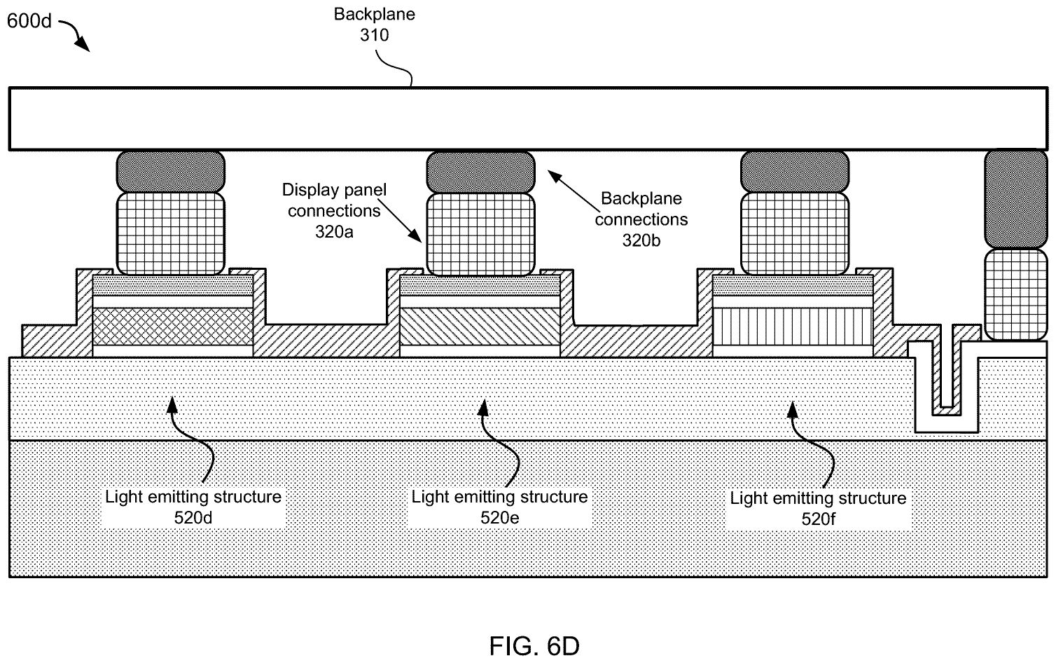

A diagram 600a in FIG. 6A illustrates a cross sectional view of an example of a device that uses the light emitting structures 520a, 520b, and 520c described above in connection with FIG. 5A. The device in this example may be used in a display panel and includes a passivation layer 620 (e.g., corresponding to the passivation layer 560) deposited between the light emitting structures, as well as a contact metal 610 (e.g., n-contact metal) at the end of the device (rightmost side). The passivation layer 620 does not cover a top portion of the conductive contact layer 550 in each of the light emitting structures to enable electrical contact to be made to the structures as shown in a diagram 600b in FIG. 6B. In the diagram 600b, the backplane 310 (see e.g., FIG. 3) may be connected to the device in FIG. 6A through connections 320. In this example, the connections 320 may include display panel connections 320a in contact with the conductive layer 550, and corresponding backplane connections 320b on the backplane 310. While the display panel connections 320a and the backplane connection 320b are shown as bumps, other types of connections may also be used to allow electrical connectivity between the backplane 310 and each of the light emitting structures 520a, 520b, and 520c through their respective conductive contact layers 550.

A diagram 600c in FIG. 6C illustrates a cross sectional view of an example of a device that uses the light emitting structures 520d, 520e, and 520f described above in connection with FIG. 5B. The device in this example may be used in a display panel and includes a passivation layer 620 (corresponding to the passivation layer 560) deposited between the light emitting structures, as well as a contact metal 610 (e.g., n-contact metal) at the end of the device (rightmost side). The passivation layer 620 does not cover a top portion of the conductive contact layer 550 in each of the light emitting structures to enable electrical contact to be made to the structures as shown in a diagram 600d in FIG. 6D. In the diagram 600d, the backplane 310 may be connected to the device in FIG. 6C through connections 320. In this example, the connections 320 may include display panel connections 320a in contact with the conductive layer 550, and corresponding backplane connections 320b on the backplane 310. While the display panel connections 320a and the backplane connection 320b are shown as bumps, other types of connections may also be used to allow electrical connectivity between the backplane 310 and each of the light emitting structures 520d, 520e, and 520f through their respective conductive contact layers 550.

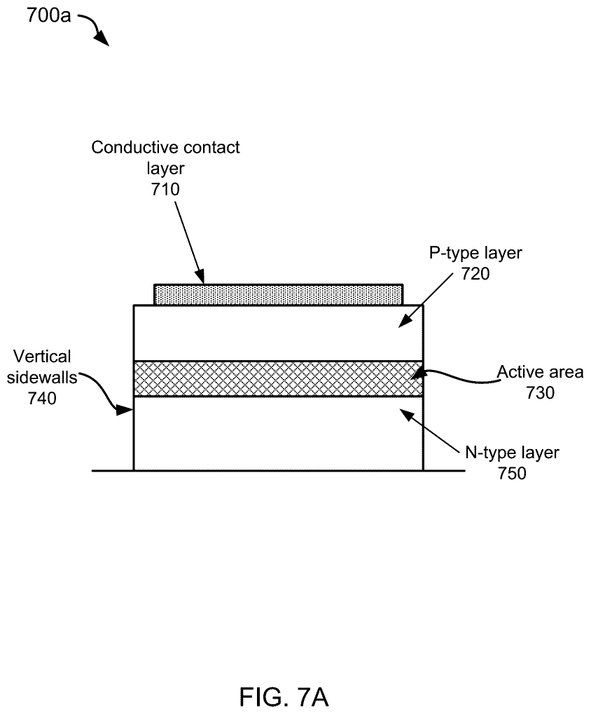

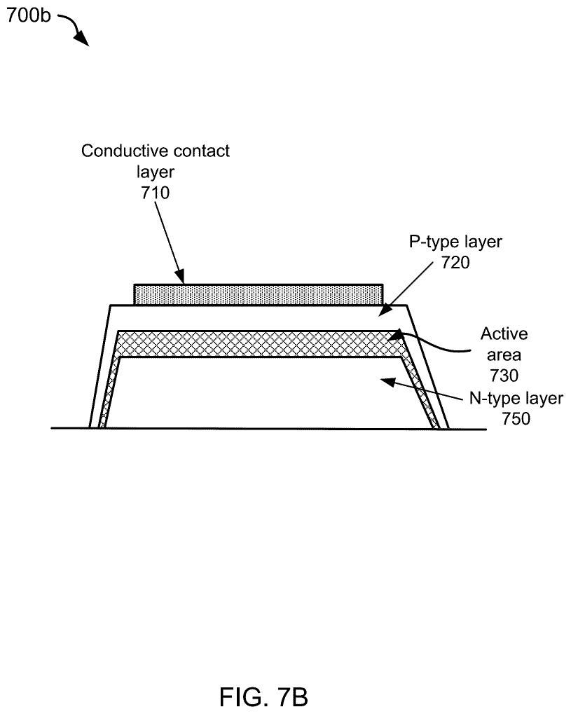

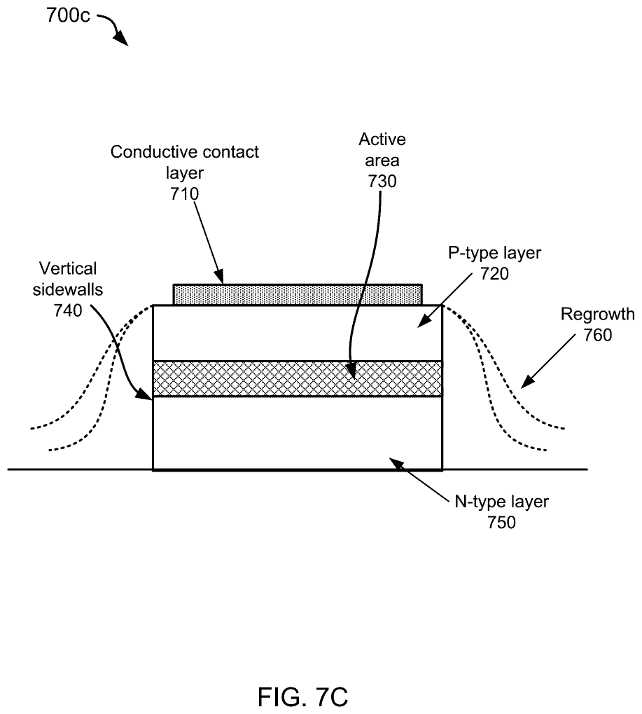

FIGS. 7A-7C illustrate diagrams 700a, 700b, and 700c that show cross sectional views of examples of light emitting structures, in accordance with aspects of this disclosure. For example, the diagram 700a shows a light emitting structure that includes multiple layers. The light emitting structure may include an n-type layer 750, an active area 730 over the n-type layer 750, a p-type layer 720 over the active area 730, and a conductive layer 710 over the p-type layer 720. The active area 730 may include one or more quantum wells, whether in the form of individual quantum well structures or as part of a MQW structure, to produce the appropriate color of light. Additionally or alternatively, the active area 730 may include one or more rare earths to produce the appropriate color of light. The active area 730 may correspond to the active area of the regions 530, the p-type layer 720 may correspond to the highly doped layer 540, and the conductive layer 710 may correspond to the conductive contact layer 550 described above. The n-type layer 750 and the active area 730 may be part of the region 530 also described above. The light emitting structure in the diagram 700a may be an example of the light emitting structures 520d, 520e, and 520f described above in connection with FIGS. 5B, 6C, and 6D having vertical sidewalls, such as vertical sidewalls 740, for example.

The diagram 700b shows a different light emitting structure that also includes multiple layers. The light emitting structure in this example includes the n-type layer 750, the active area 730 over the n-type layer 750, the p-type layer 720 over the active area 730, and the conductive layer 710 over the p-type layer 720. Unlike the example in the diagram 700a, these layers are grown or deposited in such a way that they bend downwards at the end of the structure. The active area 730 may include one or more quantum wells, whether in the form of individual quantum well structures or as part of a MQW structure, to produce the appropriate color of light. The one or more quantum wells may also be constructed in such a way that they bend downwards at the end of the structure within the active area 730. Additionally or alternatively, the active area 730 may include one or more rare earths to produce the appropriate color of light. The active area 730 may correspond to the active area of the regions 530, the p-type layer 720 may correspond to the highly doped layer 540, and the conductive layer 710 may correspond to the conductive contact layer 550 described above. The n-type layer 750 and the active area 730 may be part of the region 530 also described above. Because of its faceted or slanted ends, the light emitting structure in the diagram 700b may be different from the light emitting structures 520d, 520e, and 520f described above in connection with FIGS. 5B, 6C, and 6D having vertical sidewalls.

The diagram 700c shows a similar example to the one in the diagram 700a. In this case, however, a material regrowth may be performed to add a regrowth 760 to the sides of the light emitting structure. The regrowth 760 may vary based on the process characteristics as shown by the different dashed lines indicating the shape of the regrowth 760.

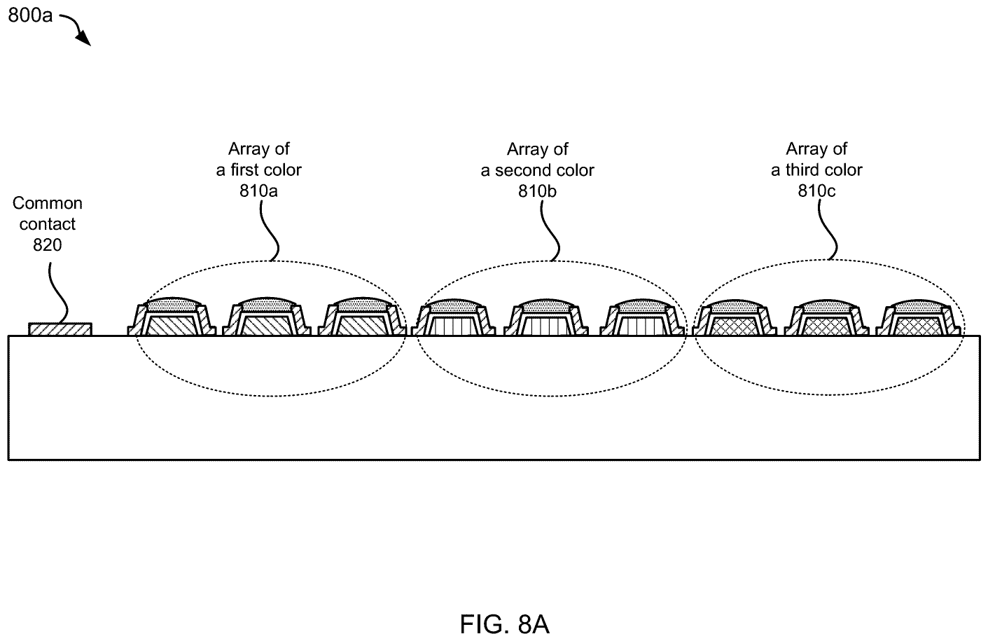

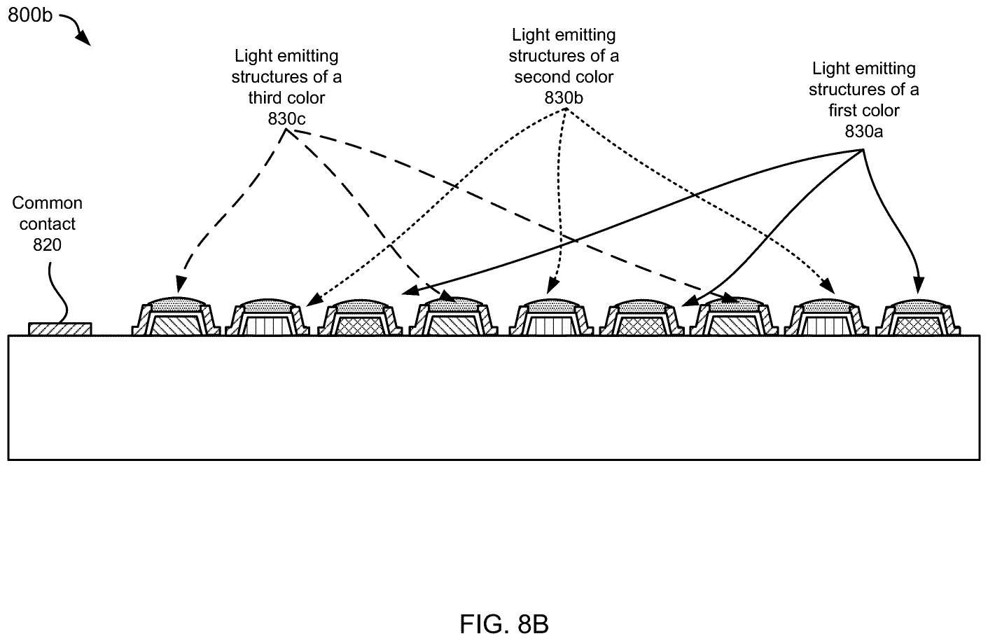

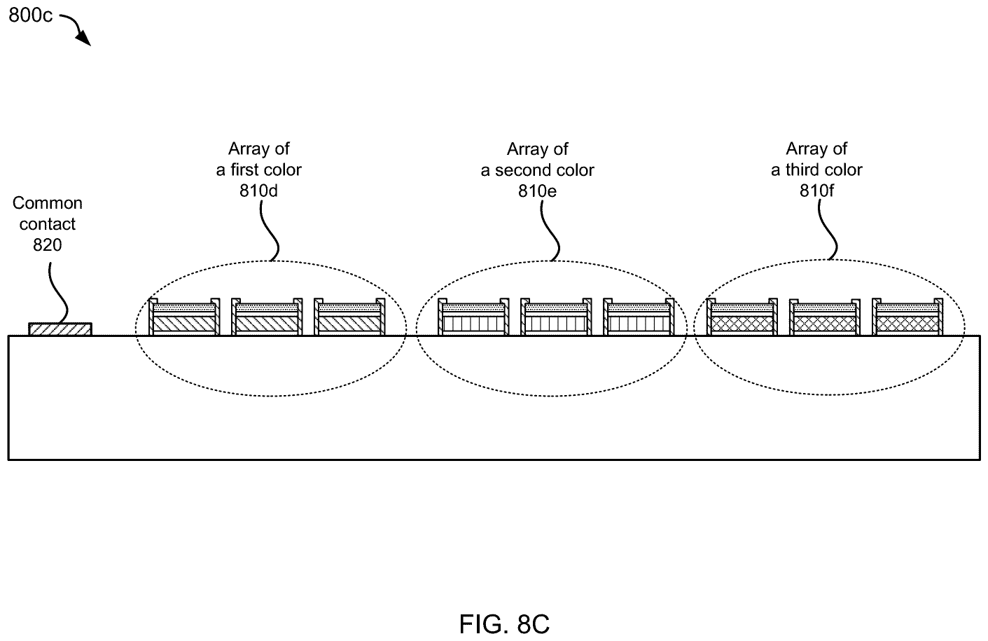

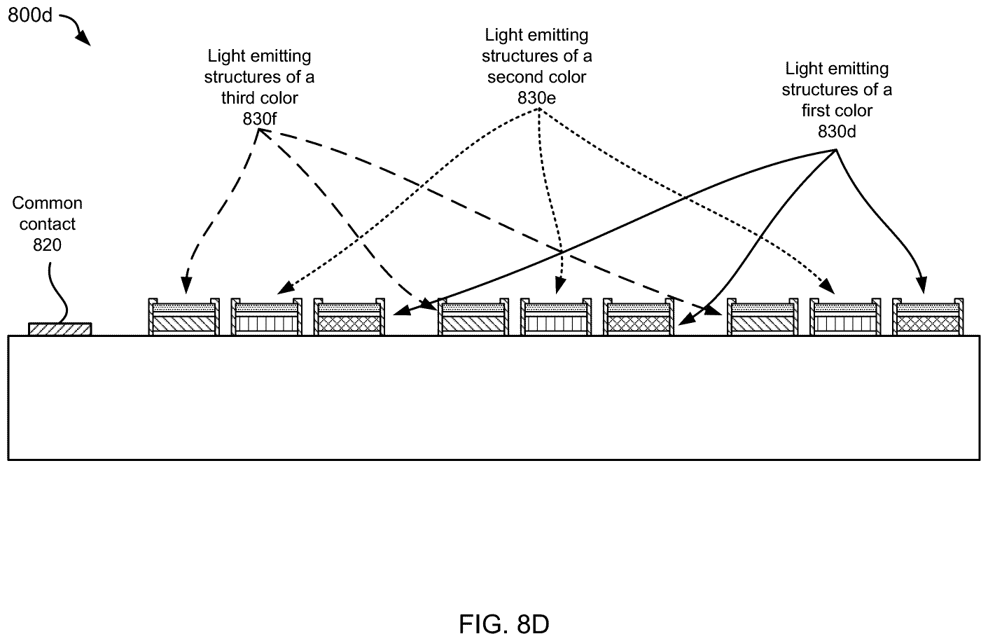

FIGS. 8A and 8B illustrate diagrams 800a and 800b, respectively, that show cross sectional views of arrays or groups of one type of light emitting structures. For example, a device in the diagram 800a may have a first array 810a of light emitting structures that produce a first color of light, a second array 810b of light emitting structures that produce a second color of light, and a third array 810c of light emitting structures that produce a third color of light. In an example, these light emitting structures may be similar to the type of light emitting structures in the diagram 500a in FIG. 5A (e.g., light emitting structures 520a, 520b, and 520c). Although only three different light emitting structures, and therefore three different types of colors, are shown, it is to be understood that the number of light emitting structures may be larger or smaller than three. In this example, light emitting structures that produce the same color of light may be placed together to form the arrays. These arrays may be consistent with, for example, the arrangement of sub-picture elements described in the diagram 400b in FIG. 4B. In the example in the diagram 800a, a common contact 820 may be used for all of the light emitting structures in the various arrays 810a, 810b, and 810c.

A device in the diagram 800b may have a first group 830a of light emitting structures that produce a first color of light, a second group 830b of light emitting structures that produce a second color of light, and a third group 830c of light emitting structures that produce a third color of light. In an example, these light emitting structures may be similar to the type of the light emitting structures in the diagram 500a in FIG. 5A (e.g., light emitting structures 520a, 520b, and 520c). Although only three different light emitting structures, and therefore three different types of colors, are shown, it is to be understood that the number of light emitting structures may be larger or smaller than three. In this example, light emitting structures that produce the same color of light may be placed in some sequence (e.g., a two dimensional sequence or arrangement). These groups may be consistent with, for example, the layout or arrangement of raxels and super-raxels described in the diagram 400a in FIG. 4A. In the example in the diagram 800b, the common contact 820 may be used for all of the light emitting structures in the various groups 830a, 830b, and 830c.

FIGS. 8C and 8D illustrate diagrams 800c and 800d, respectively, that show cross sectional views of arrays or groups of another type of light emitting structures. The diagram 800c is similar to the diagram 800a and includes a device with a first array 810d of light emitting structures that produce a first color of light, a second array 810e of light emitting structures that produce a second color of light, and a third array 810f of light emitting structures that produce a third color of light. The light emitting structures in these arrays may be similar to the type of light emitting structures in the diagram 500b in FIG. 5B (e.g., light emitting structures 520d, 520e, and 520f), and these arrays may be consistent with, for example, the arrangement of sub-picture elements described in the diagram 400b in FIG. 4B

The diagram 800d is similar to the diagram 800b and includes a device with a first group 830d of light emitting structures that produce a first color of light, a second group 830e of light emitting structures that produce a second color of light, and a third group 830f of light emitting structures that produce a third color of light. The light emitting structures in these groups may be similar to the type of light emitting structures in the diagram 500b in FIG. 5B (e.g., light emitting structures 520d, 520e, and 520f), and these groups may be consistent with, for example, the layout or arrangement of raxels and super-raxels described in the diagram 400a in FIG. 4A.

The devices described above (e.g., in FIGS. 5A-6D, 7A-7C, and 8A-8D) with monolithically integrated light emitting structures on a single substrate may be part of, for example, a display panel such as the panel 150 in the diagram 100 in FIG. 1. When the device is capable of having all of the light emitting structures (light emitting elements) that are needed for the display, then a single device (e.g., a single substrate) may be sufficient. Otherwise, multiple devices may need to be combined (e.g., stitched together) to provide the number and/or density of light emitting structures (light emitting elements) that are needed for the display.

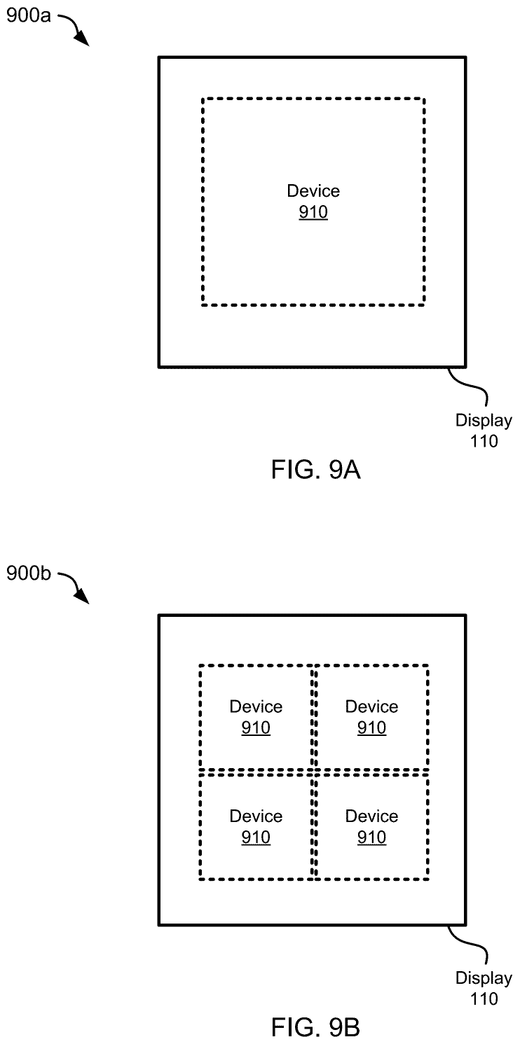

FIGS. 9A and 9B illustrate diagrams 900a and 900bm, respectively, of different examples of arrangements of devices for light generation in a display. In the diagram 900a, a single device 910 (e.g., one of the devices in FIGS. 5A-6D, 7A-7C, and 8A-8D) may have a sufficient number and/or density of monolithically integrated light emitting structures to provide the light emitting elements needed for the display 110 to operate appropriately. In the diagram 900b, a single device 910 does not have a sufficient number and/or density of monolithically integrated light emitting structures to provide the light emitting elements needed for the display 110 to operate appropriately. In such a case, multiple devices 910 may need to be combined together. The multiple devices 910 may be of the same size or of different sizes, so long as their combination has a sufficient number and/or density of monolithically integrated light emitting structures to provide the light emitting elements needed for the display 110 to operate appropriately.

In connection with the description of FIGS. 1-9B above, the present disclosure describes a device for light generation that includes a substrate (e.g., the substrate 510) having one or more buffer layers (e.g., one or more buffer or initiation layers (505) that are made at least in part of a material that includes GaN. The device may also include light emitting structures (e.g., light emitting structures 520a, . . . , 520f) epitaxially grown on a same surface of a top one of the one or more buffer layers, each light emitting structure having an active area (e.g., the active area 730) parallel to the surface and laterally terminated, and the active area of different light emitting structures being configured to directly generate a different color of light. Direct generation may refer to light generation by a transition or similar effect taking place within the active area, or between the active area and another structure physically coupled to the light emitting structure. The device may further include a p-doped layer (e.g., the highly doped layer 540, the p-type layer 720) disposed over the active area of each of the light emitting structures and made at least in part of a p-doped material that includes GaN. In this disclosure, a material that includes GaN may also refer to a material that includes a GaN alloy, for example. The active region may also be vertically confined.

In another aspect of the device for light generation, the device may also include a contact layer (e.g., the conductive contact layer 550, the conductive contact layer 710) disposed over the p-doped layer. The contact layer may be a conductive layer and is one of a metal contact layer or a transparent contact layer. In one example, the transparent contact is made of indium tin oxide (ITO), an alloy of nickel (Ni) and gold (Au), or an alloy of Ni and Au annealed with oxygen (O).

In another aspect of the device for light generation, the one or more buffer layers may be epitaxially grown on the substrate. The material from which the top one of the one or more buffer layers is made includes GaN. The material from which the one or more buffer layers are made includes a GaN alloy. The p-doped material from which the p-doped layer is made includes a GaN alloy. In some instances, the material from which the one or more buffer layers are made and the p-doped material from which the p-doped layer is made are the same material.

In another aspect of the device for light generation, the different light emitting structures may include one or more light emitting structures having their active areas made of a material that includes InGaN with a bandgap configured to directly generate blue light, one or more light emitting structures having their active areas made of a material that includes InGaN with a bandgap configured to directly generate green light, and one or more light emitting structures having their active areas made of the material that includes InGaN with a bandgap configured to directly generate red light. The different light emitting structures may further include one or more light emitting structures having their active areas made of a material that includes InGaN with a bandgap configured to directly generate a light different from blue light, green light, and red light.

In another aspect of the device for light generation, the different light emitting structures may include one or more light emitting structures having at least one quantum well in their active areas configured to directly generate blue light, one or more light emitting structures having at least one quantum well in their active areas configured to directly generate green light, and one or more light emitting structures having at least one quantum well in their active areas configured to directly generate red light. The different light emitting structures may further include one or more light emitting structures having at least one quantum well in their active areas configured to directly generate a light different from blue light, green light, and red light.

In another aspect of the device for light generation, the different light emitting structures include one or more light emitting structures having one or more rare earths in their active areas such that the active areas are configured to generate blue light, one or more light emitting structures having one or more rare earths in their active areas such that the active areas are configured to generate green light, and one or more light emitting structures having one or more rare earths in their active areas such that the active areas are configured to generate red light. The different light emitting structures may further include one or more light emitting structures having one or more rare earths in their active areas such that the active areas are configured to generate a light different from blue light, green light, and red light. The one or more rare earths include one or more of Eu, Er, Tm, Gd, or Pr (e.g., Eu3+, Er3+, Tm3+, Gd+3, Pr+3, or other charged states of these materials).

In another aspect of the device for light generation, the light emitting structures are arranged in a grid-like pattern (see e.g., FIGS. 4A and 4B). The grid-like pattern may be a square pattern, a rectangular pattern, or a hexagonal pattern, for example. The grid-like pattern may include one or more repeated sequences of the different light emitting structures.

In another aspect of the device for light generation, the active area includes a bulk active area. The active area may be doped with one or more rare earths. Examples of the one or more rare earths include one or more of Eu, Er, Tm, Gd, or Pr. In an example, any of Eu3+, Er3+, Tm3+, Gd+3, or Pr+3 may be used. These charged states are provided only by way of illustration and other charged states may also be used. The charged states used may depend on the matrix in which the rare earths are embedded. The one or more rare earths may be included in a superlattice in the active area or in a bulk active area. The active area may be laterally terminated by vertical sidewalls (e.g., the vertical sidewalls 740).

In another aspect of the device for light generation, the active area includes at least one quantum well parallel to the surface of the top one of the one or more buffer layers. The at least one quantum well may have a uniform thickness.

In another aspect of the device for light generation, each light emitting structure has faceted sidewalls (e.g., sides or sidewalls of light emitting structures 520a, 520b, 520c, and light emitting structure in the diagram 700b in FIG. 7B). The active area in these types of light emitting structure may include at least one quantum well. The faceted sidewalls are on planes other than planes perpendicular to a direction of growth of the light emitting structures.

In another aspect of the device for light generation, the active area may be laterally terminated by an epitaxially regrown passivation (see e.g., light emitting structure in the diagram 700c in FIG. 7C).

In another aspect of the device for light generation, each light emitting structure has sidewalls, and a passivation material (e.g., the passivation layer 560, 620) is disposed adjacent to the sidewalls. The passivation material may have a bandgap wider than a bandgap of GaN. The passivation material may include Ga₂O₃ or Al₂O₃. The active area may include at least one quantum well, and the passivation material may have a bandgap wider than a bandgap of the at least one quantum well. The passivation material may have an opposite doping to a doping of a corresponding portion of the light emitting structure. The passivation material may have midgap states or deep levels that are not ionized at room temperature or at an operating temperature. The sidewalls in this case may be vertical sidewalls.

In another aspect of the device for light generation, each light emitting structure has sidewalls, and a dielectric passivation (e.g., the passivation layer 560, 620) disposed adjacent to the sidewalls. A material of the dielectric passivation may have a bandgap higher than a bandgap of GaN or InGaN. The sidewalls in this case may be vertical sidewalls.

In another aspect of the device for light generation, a width of each light emitting structure or a pitch between adjacent light emitting structures is in one of the following ranges: less than 1 micron, between 1 micron and 5 microns, or greater than 5 microns.

In another aspect of the device for light generation, a contact layer (e.g., the conductive contact layer 550) may be disposed over the p-doped layer; and a connection (e.g., connections 520) may be disposed on the contact layer and configured to electrically connect each of the light emitting structures in the device to a display backplane (e.g., the backplane 310). The contact layer disposed over the p-doped layer may be a conductive layer and is one of a metal contact layer or a transparent contact layer, while the connection may be a metal bump.

In another aspect of the device for light generation, the light emitting structures may be arranged into different arrays or groups based on the different colors of light, the device further includes a first contact layer (e.g., p-type contact, the conductive contact layer 550) disposed over the p-doped layer, and a second contact layer (e.g., n-type contact, the contact 820) disposed over the top buffer layer.

In another aspect of the device for light generation, the light emitting structures may be arranged into different arrays or groups based on the different colors of light, the device further includes a first contact layer (e.g., p-type contact, the conductive contact layer 550) disposed over the p-doped layer, a second contact layer (e.g., n-type contact, the contact 820) disposed over the top buffer layer, and one or more trenches defined into the one or more buffer layers to isolate at least some of the light emitting structures.

In another aspect of the device for light generation, the light emitting structures are arranged into different arrays or groups each containing mixed colors of light emission, the device further including a first contact layer (e.g., p-type contact, the conductive contact layer 550) disposed over the p-doped layer, and a second contact layer (e.g., n-type contact, the contact 820) disposed over the top buffer layer.

In another aspect of the device for light generation, the light emitting structures are arranged into different arrays or groups each containing mixed colors of light emission, the device further includes a first contact layer (e.g., p-type contact, the conductive contact layer 550) disposed over the p-doped layer, a second contact layer (e.g., n-type contact, the contact 820) disposed over the top buffer layer, and one or more trenches defined into the one or more buffer layers to isolate at least some of the light emitting structures.

In another aspect of the device for light generation, the light emitting structures are micro light emitting devices or micro-LEDs.

In another aspect of the device for light generation, the device is part of a light field display (e.g., the light field display 210a) and is connected to a backplane of the light field display (e.g., the backplane 310).

In another aspect of the device for light generation the device is a first device (e.g., the device 910 in FIGS. 9A and 9B), a second device is substantially similar to the first device, and the first device and the second device are part of a display, such as a light field display.

The present disclosure describes various techniques and devices that enable monolithically integrating light emitting structures that generate different colors of light on a same substrate.

Accordingly, although the present disclosure has been provided in accordance with the implementations shown, one of ordinary skill in the art will readily recognize that there could be variations to the embodiments and those variations would be within the scope of the present disclosure. Therefore, many modifications may be made by one of ordinary skill in the art without departing from the scope of the appended claims.

1. (canceled)

2. A micro-LED display comprising:
a semiconductor substrate; and
a red micro-LED, a green micro-LED, and a blue micro-LED disposed on the semiconductor substrate,
at least one of the red micro-LED, the green micro-LED, or the blue micro-LED including:
a mesa having at least one quantum well with a vertical sidewall; and
a regrown semiconductor material disposed on the vertical sidewall.

3. The micro-LED display of claim 2, wherein the regrown semiconductor material has a non-vertical sidewall.

4. The micro-LED display of claim 2, wherein the regrown semiconductor material is disposed around the mesa.

5. The micro-LED display of claim 2, wherein the at least one quantum well terminates at the regrown semiconductor material.

6. The micro-LED display of claim 2, wherein the mesa has a vertical sidewall.

7. The micro-LED display of claim 2, wherein at least one of the red micro-LED, the green micro-LED, or the blue micro-LED has a non-vertical sidewall.

8. The micro-LED display of claim 7, wherein the non-vertical sidewall includes slanted facets.

9. The micro-LED display of claim 2, wherein the semiconductor substrate is conductive.

10. The micro-LED display of claim 2, wherein the red micro-LED, the green micro-LED, and the blue micro-LED are monolithically grown on the semiconductor substrate.

11. The micro-LED display of claim 2, wherein the mesa includes a plurality of quantum wells, the plurality of quantum wells having respective vertical sidewalls.

12. A method of forming a micro-LED display, comprising:
growing, on a semiconductor substrate, a red LED mesa, a green LED mesa, and a blue LED mesa, each mesa respectively including at least one quantum well;
defining a vertical sidewall of the at least one quantum well of at least one of to the red LED mesa, the green LED mesa, or the blue LED mesa; and
forming a regrown semiconductor material around the vertical sidewall.

13. The method of claim 12, wherein the regrown semiconductor material has a non-vertical sidewall.

14. The method of claim 12, wherein the regrown semiconductor material is disposed around the at least one of the red LED mesa, the green LED mesa, or the blue LED mesa.

15. The method of claim 12, wherein the at least one quantum well of at least one of to the red LED mesa, the green LED mesa, or the blue LED mesa terminates at the regrown semiconductor material.

16. The method of claim 12, wherein the at least one of the red LED mesa, the green LED mesa, or the blue LED mesa has a vertical sidewall.

17. The method of claim 12, wherein at the least one of the red LED mesa, the green LED mesa, or the blue LED mesa has a non-vertical sidewall.

18. The method of claim 17, wherein the non-vertical sidewall includes slanted facets.

19. The method of claim 12, wherein the semiconductor substrate is conductive.

20. The method of claim 12, wherein growing the red LED mesa, the green LED mesa, and the blue LED mesa includes monolithically growing the red LED mesa, the green LED mesa, and the blue LED mesa on the semiconductor substrate.

21. The method of claim 12, wherein the at least one quantum well includes a plurality of quantum wells, the plurality of quantum wells having respective vertical sidewalls.
